(19) United States
(12) Patent Application Publication
(10) Pub. No.: US 2026/0279477 A1
(43) Pub. Date: Sep. 17, 2026

(54) SEMICONDUCTOR MEMORY DEVICE

(71) Applicant: Kioxia Corporation, Tokyo (JP)

(72) Inventors: Katsuaki SAKURAI, Yokohama Kanagawa (JP); Hiroki IDE, Fujisawa Kanagawa (JP)

(73) Assignee: Kioxia Corporation, Tokyo (JP)

(21) Appl. No.: 19/300,907

(22) Filed: Aug. 15, 2025

(30) Foreign Application Priority Data
Mar. 17, 2025 (JP) 2025-042795

(51) Int. Cl. G11C 29/12; G11C 16/08; G11C 16/30; G11C 16/34

(52) U.S. Cl. CPC G11C 29/12005; G11C 16/08; G11C 16/30; G11C 16/3454; G11C 2029/1202

(57) ABSTRACT

According to an embodiment, a semiconductor memory device includes a memory cell array including a memory cell, a word line coupled to the memory cell, a row decoder to which the word line is coupled, a first interconnect coupled to the row decoder, a voltage generator configured to execute charge and discharge of the word line via the first interconnect and the row decoder, a detection circuit included in the voltage generator and configured to output a first signal based on the discharge of the word line, and a determination circuit configured to determine whether the word line is nondefective or defective, based on the first signal.

### CROSS-REFERENCE TO RELATED APPLICATION

This application is based upon and claims the benefit of priority from prior Japanese Patent Application No. 2025-042795, filed Mar. 17, 2025, the entire contents of which are incorporated herein by reference.

### FIELD

Embodiments described herein relate generally to a semiconductor memory device.

### BACKGROUND

A NAND flash memory of a three-dimensional stack type is known as a semiconductor memory device.

### BRIEF DESCRIPTION OF THE DRAWINGS

FIG. 1 is a block diagram illustrating an example of an overall configuration of a semiconductor memory device according to a first embodiment.

FIG. 2 is a circuit diagram illustrating an example of a circuit configuration of a memory cell array included in the semiconductor memory device according to the first embodiment.

FIG. 3 is a circuit diagram illustrating an example of a configuration of a row decoder included in the semiconductor memory device according to the first embodiment.

FIG. 4 is a diagram schematically illustrating an example of couplings between a logic control circuit, a sequencer, a voltage generator, the memory cell array, and the row decoder included in the semiconductor memory device according to the first embodiment.

FIG. 5 is a diagram illustrating threshold voltage distributions and data assignment in a case where a memory cell transistor included in the semiconductor memory device according to the first embodiment is a triple level cell (TLC).

FIG. 6 is a timing chart illustrating an example of a voltage of each of interconnects in a word line determination operation in the semiconductor memory device according to the first embodiment.

FIG. 7 is a flowchart illustrating an example of a flow of the word line determination operation in the semiconductor memory device according to the first embodiment.

FIG. 8 is a flowchart illustrating a flow of a write operation in a first example of a combination of a program verify operation and a word line determination operation in a semiconductor memory device according to a second embodiment.

FIG. 9 is a timing chart illustrating a voltage of each of interconnects in the program verify operation and the word line determination operation in the first example in the semiconductor memory device according to the second embodiment.

FIG. 10 is a timing chart illustrating a voltage of each of interconnects in a program verify operation and a word line determination operation in a second example in the semiconductor memory device according to the second embodiment.

FIG. 11 is a diagram schematically illustrating an example of couplings between a logic control circuit, a sequencer, a voltage generator, a memory cell array, and a row decoder included in a semiconductor memory device according to a third embodiment.

FIG. 12 is a timing chart illustrating an example of a voltage of a word line WL in a word line determination operation in the semiconductor memory device according to the third embodiment.

FIG. 13 is a diagram schematically illustrating an example of couplings between a logic control circuit, a sequencer, a voltage generator, a memory cell array, and a row decoder included in a semiconductor memory device according to a fourth embodiment.

### DETAILED DESCRIPTION

In general, according to one embodiment, a semiconductor memory device includes a memory cell array including a memory cell, a word line coupled to the memory cell, a row decoder to which the word line is coupled, a first interconnect coupled to the row decoder, a voltage generator configured to execute charge and discharge of the word line via the first interconnect and the row decoder, a detection circuit included in the voltage generator and configured to output a first signal based on the discharge of the word line, and a determination circuit configured to determine whether the word line is nondefective or defective, based on the first signal.

Hereinafter, embodiments are described with reference to the accompanying drawings. In the description below, common reference signs are added to structural elements having identical functions and structures. In addition, in a case of distinguishing structural elements having common reference signs, the structural elements are distinguished by adding additional characters to the common reference signs. If structural elements do not need to be particularly distinguished, only common reference signs are added to the structural elements, and no additional characters are added. Here, the additional characters are not limited to subscripts and superscripts, and include, for example, lowercase alphabet, an index indicating an arrangement, and the like, which are added to ends of reference signs.

### 1. First Embodiment

A semiconductor memory device according to a first embodiment is described.

### 1.1. Configuration

### 1.1.1. Overall Configuration of Semiconductor Memory Device

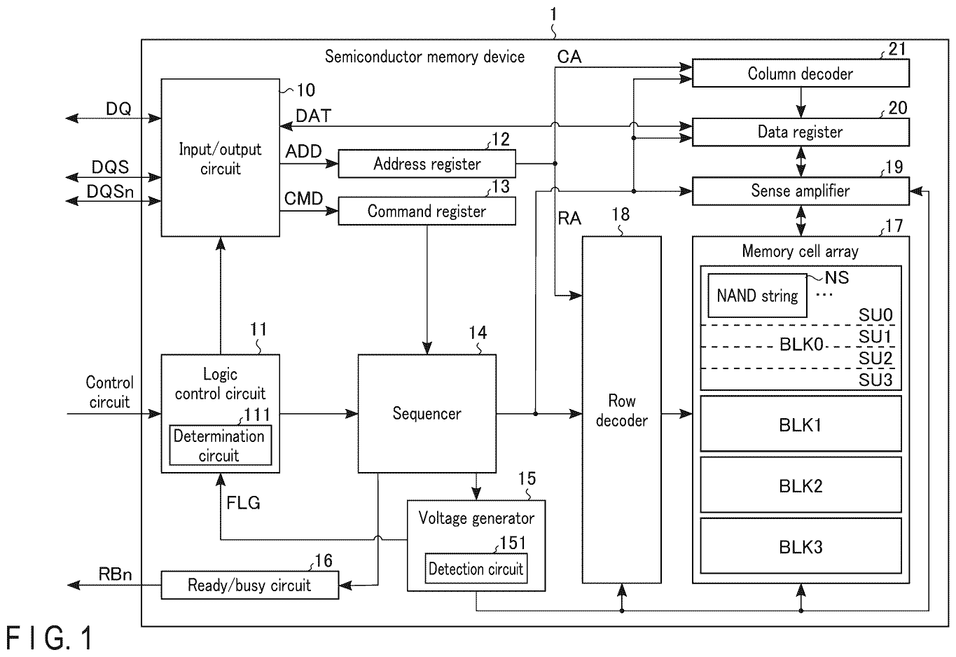

At first, referring to FIG. 1, an example of an overall configuration of a semiconductor memory device 1 is described. FIG. 1 is a block diagram illustrating an example of an overall configuration of the semiconductor memory device 1. Note that in FIG. 1, although some of couplings between components are indicated by arrows, the couplings between the components are not limited to this.

As illustrated in FIG. 1, the semiconductor memory device 1 is, for example, a three-dimensional stack-type NAND flash memory. In the three-dimensional stack-type NAND flash memory, nonvolatile memory cell transistors are disposed three-dimensionally above a semiconductor substrate. Note that the semiconductor memory device 1 is not limited to the three-dimensional stack-type NAND flash memory.

The semiconductor memory device 1 is coupled to a memory controller (not illustrated) that is provided on the outside. The semiconductor memory device 1 operates, based on an instruction (request) from the memory controller, or based on a spontaneous request. The semiconductor memory device 1 transmits and receives a signal DQ and clock signals DQS and DQSn to and from the memory controller. The signal DQ is, for example, data DAT, an address ADD, or a command CMD. The clock signals DQS and DQSn are clock signals that are used at a time of inputting and outputting the data DAT. The clock signal DQSn is an inverted signal of the clock signal DQS. The semiconductor memory device 1 receives various control signals from the memory controller. In addition, the semiconductor memory device 1 transmits a ready/busy signal RBn to the memory controller. The ready/busy signal RBn is a signal indicating whether the semiconductor memory device 1 is in a busy state or in a ready state. The busy state is a state in which the semiconductor memory device 1 cannot receive the signal DQ from the memory controller. The ready state is a state in which the semiconductor memory device 1 can receive the signal DQ from the memory controller.

Next, an internal configuration of the semiconductor memory device 1 is described. The semiconductor memory device 1 includes an input/output circuit 10, a logic control circuit 11, an address register 12, a command register 13, a sequencer 14, a voltage generator 15, a ready/busy circuit 16, a memory cell array 17, a row decoder 18, a sense amplifier 19, a data register 20, and a column decoder 21.

The input/output circuit 10 is a circuit that inputs and outputs the signal DQ. The input/output circuit 10 is coupled to the memory controller. In addition, the input/output circuit 10 is coupled to the address register 12, the command register 13, and the data register 20. In the case where the signal DQ is the data DAT, the input/output circuit 10 receives the signal DQ, based on the clock signals DQS and DQSn. Then, the input/output circuit 10 sends the data DAT to the data register 20. In addition, the input/output circuit 10 outputs the data DAT, together with the clock signals DQS and DQSn, to the memory controller. In the case where the signal DQ is the address ADD, the input/output circuit 10 sends the address ADD to the address register 12. In the case where the signal DQ is the command CMD, the input/output circuit 10 sends the command CMD to the command register 13.

The logic control circuit 11 is a circuit that executes logic control, based on the control signals. The logic control circuit 11 is coupled to the memory controller. In addition, the logic control circuit 11 is coupled to the input/output circuit 10, the sequencer 14, and the voltage generator 15. The logic control circuit 11 receives various control signals from the memory controller. Based on the received control signals, the logic control circuit 11 controls the input/output circuit 10 and sequencer 14.

The logic control circuit 11 includes a determination circuit 111.

The determination circuit 111 is a circuit that determines whether a word line is nondefective (normal) or defective (abnormal). The word line is an interconnect that is coupled to the gate of a memory cell transistor. The details of the coupling of the word line will be described later. For example, if abnormality occurs in the word line, the resistance value of the word line increases. Thus, the determination circuit 111 can also be described as being a circuit that determines whether the resistance of the word line is high or not. The determination circuit 111 is coupled to the sequencer 14 and a detection circuit 151 of the voltage generator 15. The determination circuit 111 receives a signal FLG from the detection circuit 151. The signal FLG is a signal based on discharge of the word line. The signal FLG will be described later. Using the signal FLG, the determination circuit 111 executes the determination of the word line. More specifically, the determination circuit 111 includes a counter (not illustrated). The counter executes counting, based on an arbitrary clock, during a period in which the signal FLG is at High (“H”) level. In other words, the determination circuit 111 can convert the length of the period, during which the signal FLG is at “H” level, into a count number. The length of the period, during which the signal FLG is at “H” level, increases as the resistance value of the word line becomes higher. That is, the count number increases as the resistance value of the word line becomes higher. In a case where the count number is less than a preset determination value, the determination circuit 111 determines that the word line is nondefective (that is, low resistance). On the other hand, in a case where the count number is equal to or greater than the preset determination value, the determination circuit 111 determines that the word line is defective (that is, high resistance). The determination circuit 111 sends the determination result to the sequencer 14. Note that the determination circuit 111 may determine the degree of degradation of the word line (the increase rate of the resistance value) by comparing the initial value of the count number with the count result.

The address register 12 is a register that temporarily stores the address ADD. The address register 12 is coupled to the row decoder 18 and the column decoder 21. The address ADD includes a row address RA and a column address CA. The address register 12 transfers the row address RA to the row decoder 18. In addition, the address register 12 transfers the column address CA to the column decoder 21.

The command register 13 is a register that temporarily stores the command CMD. The command register 13 is coupled to the sequencer 14. The command register 13 transfers the command CMD to the sequencer 14.

The sequencer 14 is a circuit that executes control of the semiconductor memory device 1. The sequencer 14 controls the operation of the entirety of the semiconductor memory device 1. More specifically, the sequencer 14 controls the voltage generator 15, the ready/busy circuit 16, the row decoder 18, the sense amplifier 19, the data register 20, and the column decoder 21. Note that the sequencer 14 may control the determination circuit 111. For example, based on the command CMD, the sequencer 14 executes a write operation, a read operation, or an erase operation. In addition, the sequencer 14 of the present embodiment executes a word line determination operation. The word line determination operation is an operation of determining whether the word line is nondefective or defective. The word line determination operation will be described later.

The voltage generator 15 generates various voltages that are used for the write operation, the read operation, and the erase operation. For example, the voltage generator 15 is coupled to the logic control circuit 11, the memory cell array 17, the row decoder 18, and the sense amplifier 19. For example, the voltage generator 15 supplies the various voltages to the memory cell array 17, the row decoder 18, and the sense amplifier 19.

The voltage generator 15 includes the detection circuit 151. The detection circuit 151 of the present embodiment integrates the discharge current during an arbitrary period at the time of discharging the word line, and detects the variation of the total charge amount. The details of the configuration of the detection circuit 151 will be described later. For example, if the resistance value of the word line increases, the RC time constant increases. Thus, the discharge rate of the word line becomes lower (the discharge time becomes longer). The total charge amount of the discharge current in the arbitrary period after the start of discharge tends to increase if the resistance of the word line becomes higher. Based on the total charge amount, the detection circuit 151 varies the length of the period during which the signal FLG is at “H” level. The period during which the signal FLG is at “H” level becomes longer as the total charge amount is greater, that is, as the resistance value of the word line is higher.

The ready/busy circuit 16 is a circuit that transmits the ready/busy signal RBn. In accordance with the operation state of the sequencer 14, the ready/busy circuit 16 transmits the ready/busy signal RBn to the memory controller.

The memory cell array 17 is a set of memory cell transistors (also referred to as “memory cells”) that are arranged. The memory cell array 17 includes a plurality of blocks BLK. In the example illustrated in FIG. 1, the memory cell array 17 includes blocks BLK0, BLK1, BLK2 and BLK3. The block BLK is, for example, a set of memory cell transistors from which data is erased collectively. The memory cell transistors in the block BLK are associated with rows and columns. The block BLK includes a plurality of string units SU. In the example illustrated in FIG. 1, the block BLK includes four string units SU0, SU1, SU2 and SU3. The string unit SU is, for example, a set of NAND strings NS that are selected collectively in the write operation or the read operation. The string unit SU includes a plurality of NAND strings NS. The NAND string NS includes a set of memory cell transistors that are coupled in series. Note that the number of blocks BLK in the memory cell array 17 and the number of string units SU in the block BLK are arbitrary. The details of the memory cell array 17 will be described later.

The row decoder 18 is a circuit that decodes the row address RA. The row decoder 18 is coupled to the memory cell array 17. The row decoder 18 receives the row address RA from the address register 12. Based on the decoded result of the row address RA, the row decoder 18 selects one of the blocks BLK in the memory cell array 17. Then, the row decoder 18 supplies voltages to interconnects (word lines and select gate lines) in the row direction of the selected block BLK.

The sense amplifier 19 is a circuit that executes write and read of the data DAT. The sense amplifier 19 is coupled to the memory cell array 17. At the time of the read operation, the sense amplifier 19 reads the data DAT from the memory cell array 17. In addition, at the time of the write operation, the sense amplifier 19 supplies voltages corresponding to the write data DAT to the memory cell array 17.

The data register 20 is a register that temporarily stores the data DAT. The data register 20 is coupled to the sense amplifier 19. The data register 20 includes a plurality of latch circuits. Each latch circuit temporarily stores write data DAT or read data DAT.

The column decoder 21 is a circuit that decodes the column address CA. The column decoder 21 receives the column address CA from the address register 12. Based on the decoded result of the column address CA, the column decoder 21 selects the latch circuits in the data register 20.

### 1.1.2. Circuit Configuration of Memory Cell Array

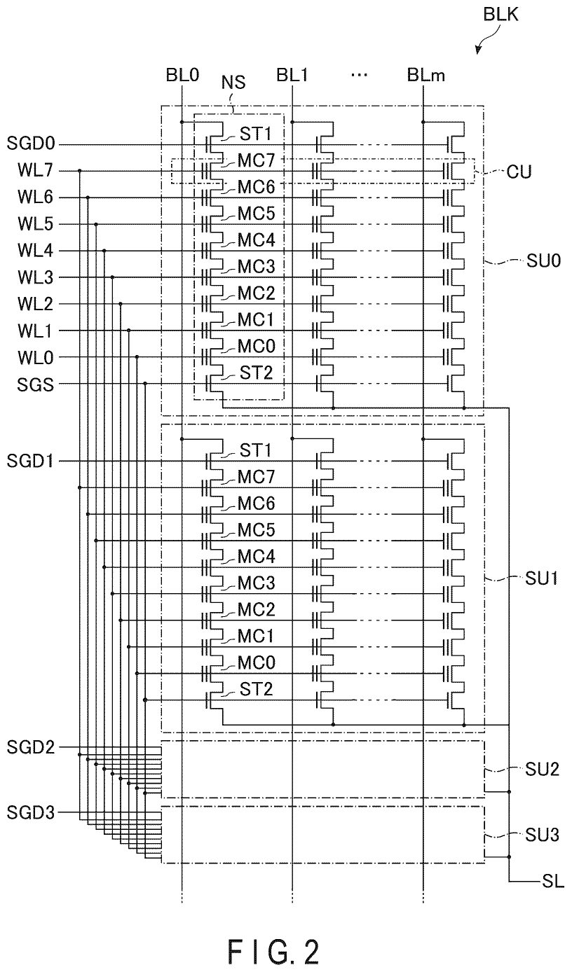

Next, referring to FIG. 2, a circuit configuration of the memory cell array 17 is described. FIG. 2 is a circuit diagram illustrating an example of a circuit configuration of the memory cell array 17. The example in FIG. 2 illustrates one block BLK, and the configuration of this one block BLK is the same as the configuration of each of the other blocks BLK.

As illustrated in FIG. 2, each of the blocks BLK includes, for example, four string units SU0 to SU3. In addition, each of the string units SU includes a plurality of NAND strings NS. Each of the NAND strings NS in the string unit SU is coupled to one of bit lines BL0 to BLm (m is an integer of 1 or more). Each NAND string NS includes, for example, eight memory cell transistors MC (MC0 to MC7), and select transistors ST1 and ST2. Note that the number of memory cell transistors MC in the NAND string NS is not limited to eight. In addition, each of the number of select transistors ST1 and the number of select transistors ST2 in the NAND string NS may be one or more.

The memory cell transistor MC is a memory element that stores data in a nonvolatile manner. The memory cell transistor MC includes a control gate and a charge storage layer. The memory cell transistor MC may be of a metal-oxide-nitride-oxide-silicon (MONOS) type using an insulator as the charge storage layer, or may be of a floating gate (FG) type using a conductor as the charge storage layer.

The select transistors ST1 and ST2 are switching elements. The select transistors ST1 and ST2 are used to select the string unit SU at times of various operations.

Current paths of the select transistor ST2, memory cell transistors MC0 to MC7 and select transistor ST1 in the NAND string NS are coupled in series. The drain of the select transistor ST1 is coupled to the bit line BL. The source of the select transistor ST2 is coupled to a source line SL.

The control gates of the memory cell transistors MC0 to MC7 of the same block BLK are commonly coupled to word lines WL0 to WL7. More specifically, for example, each of the string units SU0 to SU3 includes a plurality of memory cell transistors MC0. The control gates of the memory cell transistors MC0 included in the string units SU0 to SU3 are commonly coupled to one word line WL0. That is, the control gates of the memory cell transistors MC0 in the block BLK are commonly coupled to one word line WL0. The same applies to the memory cell transistors MC1 to MC7. The gates of the select transistors ST1 in each string unit SU are commonly coupled to one select gate line SGD. More specifically, the gates of the select transistors ST1 in the string unit SU0 are commonly coupled to a select gate line SGD0. The gates of the select transistors ST1 in the string unit SU1 are commonly coupled to a select gate line SGD1. The gates of the select transistors ST1 in the string unit SU2 are commonly coupled to a select gate line SGD2. The gates of the select transistors ST1 in the string unit SU3 are commonly coupled to a select gate line SGD3.

The gates of the select transistors ST2 in the block BLK are commonly coupled to a select gate line SGS.

The word lines WL0 to WL7, the select gate lines SGD0 to SGD3, and the select gate line SGS are coupled to the row decoder 18.

The bit line BL is commonly coupled to one NAND string NS of each of the string units SU of each block BLK. Each of the bit lines BL is coupled to the sense amplifier 19.

The source line SL is, for example, shared between a plurality of blocks BLK.

A set of memory cell transistors MC coupled to a common word line WL in one string unit SU is referred, for example, as “cell unit CU”. In other words, the cell unit CU is a set of memory cell transistors MC that are selected collectively in the write operation or the read operation. A page is a unit of data that is written collectively (or is read collectively). For example, in a case where the memory cell transistor MC stores 1-bit data, the storage capacity of the cell unit CU is one page. That is, the cell unit CU stores 1-page data. Note that the cell unit CU can have a storage capacity of two or more pages, based on the number of bits of data that the memory cell transistor MC stores. The memory cell transistor MC may be a single level cell (SLC) that stores 1-bit data, or may be a multi level cell (MLC) that stores 2-bit data. Further, the memory cell transistor MC may be a triple level cell (TLC) that stores 3-bit data, a quad level cell (QLC) that stores 4-bit data, or a penta level cell (PLC) that stores 5-bit data. Hereinafter, in the present embodiment, a case is described in which the memory cell transistor MC is the TLC.

### 1.1.3. Configuration of Row Decoder

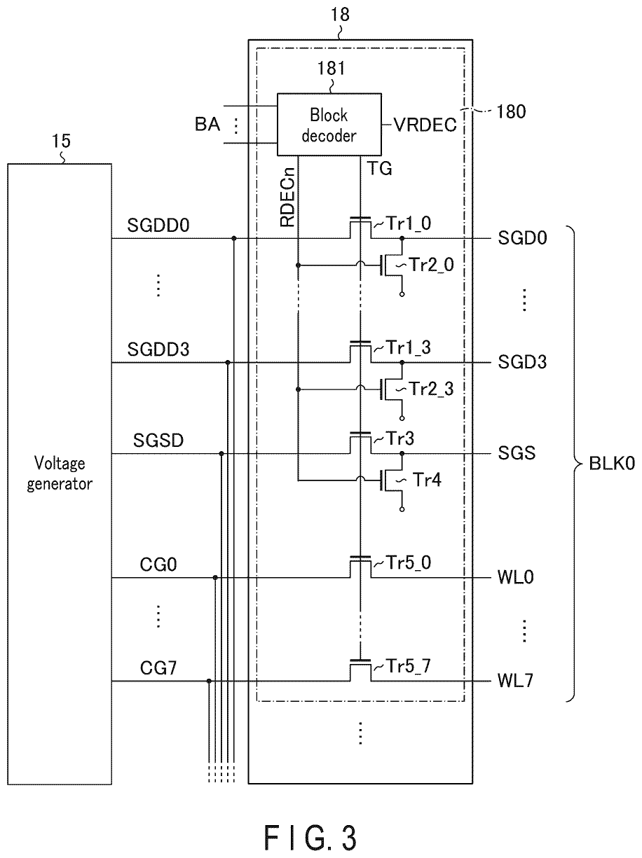

Next, referring to FIG. 3, an example of a configuration of the row decoder 18 is described. FIG. 3 is a circuit diagram illustrating an example of a configuration of the row decoder 18. In the example illustrated in FIG. 3, for the purpose of simple description, the depiction of the select gate lines SGD1 and SGD2, word lines WL1 to WL6, and transistors Tr coupled to these is omitted.

Note that in the description below, in a case where the source and the drain of a transistor are not specified, one of the source and drain of the transistor is referred as “one end of the transistor”, and the other of the source and drain of the transistor is referred as “the other end of the transistor”.

As illustrated in FIG. 3, the row decoder 18 includes a row decoder unit 180 that is associated with each block BLK. Note that in the example illustrated in FIG. 3, although the details of the row decoder unit 180 corresponding to the block BLK0 are illustrated, the row decoder units 180 corresponding to the other blocks BLK have the same configuration.

The row decoder unit 180 includes a block decoder 181, and high-breakdown-voltage n-channel MOS transistors Tr1 (Tr1_0 to Tr1_3), Tr2 (Tr2_0 to Tr2_3), Tr3, Tr4, and Tr5 (Tr5_0 to Tr5_7). Hereinafter, the high-breakdown-voltage transistor Tr is referred simply as “transistor Tr”.

The block decoder 181 decodes a block address BA. The block address BA is an address that designates the block BLK and included in the row address RA. In addition, in accordance with the decoded result, the block decoder 181 applies voltages to a signal line TG and a signal line RDECn, and controls the ON state and OFF state of the transistors Tr1 to Tr5.

For example, in the write operation, the read operation, or the erase operation, in a case where the block address BA coincides with the corresponding block BLK0, the block decoder 181 applies a voltage of “H” level (for example, voltage VRDEC) to the signal line TG, and applies a volage of Low (“L”) level (for example, ground voltage VSS) to the signal line RDECn. Thereby, the transistors Tr1, Tr3, and Tr5 are set to an ON state, and the transistors Tr2 and Tr4 are set to an OFF state. On the other hand, in a case where the block address BA does not coincide with the corresponding block BLK0, the block decoder 181 applies a voltage of “L” level to the signal line TG, and applies a volage of “H” level to the signal line RDECn. Thereby, the transistors Tr1, Tr3, and Tr5 are set to the OFF state, and the transistors Tr2 and Tr4 are set to the ON state. The voltage VRDEC is a voltage that sets the transistors Tr1 to Tr5 in the ON stage. Different voltage values may be set for the voltage VRDEC in regard to the write operation, the read operation, and the erase operation. The voltage VRDEC is higher than the voltage that is applied to the transistors Tr1, Tr3, and Tr5 from the voltage generator 15. For example, the voltage VRDEC is supplied from the voltage generator 15 to the block decoder 181.

The transistors Tr1_0 to Tr1_3 function as switching elements that couple the voltage generator 15 to the select gate lines SGD0 to SGD3 of the corresponding block BLK, respectively. The transistors Tr1_0 to Tr1_3 are coupled, at one end, to the corresponding select gate lines SGD0 to SGD3, respectively. The transistors Tr1_0 to Tr1_3 are coupled, at the other end, to the voltage generator 15 via corresponding interconnects SGDD0 to SGDD3. The gates of the transistors Tr1_0 to Tr1_3 are commonly coupled to the signal line TG.

The transistors Tr2_0 to Tr2_3 function as switching elements that couple, for example, ground voltage interconnects to the select gate lines SGD0 to SGD3 of the corresponding block BLK, respectively. The transistors Tr2_0 to Tr2_3 are coupled, at one end, to the corresponding select gate lines SGD0 to SGD3, respectively. The transistors Tr2_0 to Tr2_3 are grounded at the other end (coupled to the ground voltage interconnects). The gates of the transistors Tr2_0 to Tr2_3 are commonly coupled to the signal line RDECn.

The transistor Tr3 functions as a switching element that couples the voltage generator 15 and the select gate line SGS of the corresponding block BLK. One end of the transistor Tr3 is coupled to the corresponding select gate line SGS. The other end of the transistor Tr3 is coupled to the voltage generator 15 via an interconnect SGSD. The gate of the transistor Tr3 is coupled to the signal line TG.

The transistor Tr4 functions as a switching element that couples, for example, a ground voltage interconnect to the select gate line SGS of the corresponding block BLK. One end of the transistor Tr4 is coupled to the corresponding select gate line SGS. The other end of the transistor Tr4 is, for example, grounded (coupled to the ground voltage interconnect). The gate of the transistor Tr4 is coupled to the signal line RDECn.

The transistors Tr5_0 to Tr5_7 function as switching elements that couple the voltage generator 15 to the word lines WL0 to WL7 of the corresponding block BLK. The transistors Tr5_0 to Tr5_7 are coupled, at one end, to the corresponding word lines WL0 to WL7, respectively. The transistors Tr5_0 to Tr5_7 are coupled, at the other end, to the voltage generator 15 via interconnects CG0 to CG7, respectively. The gates of the transistors Tr5_0 to Tr5_7 are commonly coupled to the signal line TG.

The voltage generator 15 charges and discharges the word lines WL0 to WL7 of the selected block BLK via the interconnects CG0 to CG7 and the row decoder 18.

### 1.1.4. Configuration of Detection Circuit

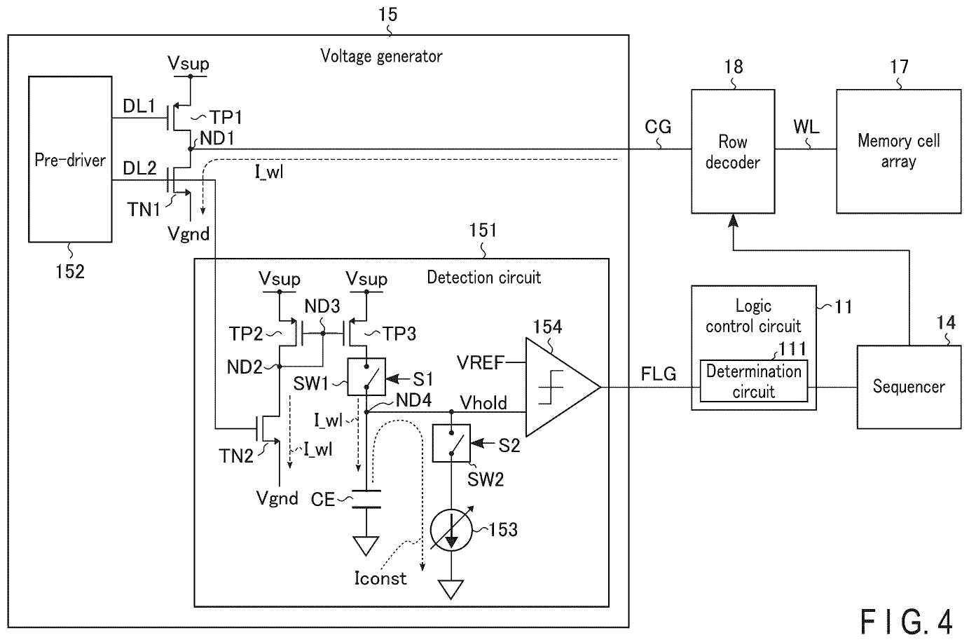

Next, referring to FIG. 4, an example of a configuration of the detection circuit 151 is described. FIG. 4 is a diagram schematically illustrating an example of couplings between the logic control circuit 11, the sequencer 14, the voltage generator 15, the memory cell array 17, and the row decoder 18. The example in FIG. 4 illustrates couplings corresponding to one word line WL, for the purpose of simple description.

As illustrated in FIG. 4, the voltage generator 15 further includes a pre-driver 152, a p-channel MOS transistor TP1, and an n-channel MOS transistor TN1. Hereinafter, the p-channel MOS transistor TP1 is referred simply as “transistor TP1”. The n-channel MOS transistor TN1 is referred simply as “transistor TN1”.

The pre-driver 152 is a driver that controls the voltage that is applied to the interconnect CG. In other words, the pre-driver 152 is a driver that controls the voltage that is applied to the word line WL. The pre-driver 152 is coupled to the gate of the transistor TP1 via an interconnect DL1. For example, a power supply voltage Vsup is applied to the source of the transistor TP1. The drain of the transistor TP1 is coupled to a node ND1. The node ND1 is coupled to the row decoder 18 via the interconnect CG.

In addition, the pre-driver 152 is commonly coupled to the gate of the transistor TN1 and the detection circuit 151 via an interconnect DL2. The drain of the transistor TN1 is coupled to the node ND1. A voltage Vgnd is applied to the source of the transistor TN1. The voltage Vgnd may be a ground voltage VSS or may be an arbitrary voltage (for example, a negative voltage) that is lower than the voltage Vsup.

For example, in a case of applying voltage to the word line WL (interconnect CG), the pre-driver 152 controls the gate voltage of the transistor TP1. For example, in a case of discharging the voltage that is applied to the word line WL (interconnect CG), the pre-driver 152 controls the gate voltage of the transistor TN1. At this time, a discharge current I_wl flows through the transistor TN1.

The detection circuit 151 includes p-channel MOS transistors TP2 and TP3 (transistors TP2 and TP3), an n-channel MOS transistor TN2 (transistor TN2), a capacitance element CE, switch circuits SW1 and SW2, a constant current circuit 153, and a comparator 154.

The transistor TN2, together with the transistor TN1, constitutes a current mirror. The interconnect DL2 is coupled to the gate of the transistor TN2. The drain of the transistor TN2 is coupled to a node ND2. A voltage Vgnd is applied to the source of the transistor TN2. For example, if the discharge current I_wl flows through the transistor TN1, the same current I_wl flows through the transistor TN2.

The transistors TP2 and TP3 constitute a current mirror. More specifically, for example, the voltage Vsup is applied to the sources of the transistors TP2 and TP3. The drain of the transistor TP2 is coupled to the node ND2. The drain of the transistor TP3 is coupled to one terminal of the switch circuit SW1. The gates of the transistors TP2 and TP3 are commonly coupled to the node ND2 via a node ND3. For example, if the current I_wl flows through the transistor TP2, the same current I_wl flows through the transistor TP3.

The other terminal of the switch circuit SW1 is coupled to a node ND4. The ON state and OFF state of the switch circuit SW1 are controlled based on a control signal S1. The control signal S1 is controlled, for example, by the sequencer 14. For example, in a case where the switch circuit SW1 is in the ON state, the current I_wl flows through the node ND4.

One electrode of the capacitance element CE is coupled to the node ND4. The other electrode of the capacitance element CE is grounded. For example, while the switch circuit SW1 is set to the ON state and the switch circuit SW2 is set to the OFF state, the capacitance element CE is charged with the current I_wl. The voltage of the node ND4 due to the charging (the voltage of the one electrode of the capacitance element CE) is referred as “voltage Vhold”. In accordance with the charge amount of the capacitance element CE, the voltage Vhold increases. Note that the charge amount of the capacitance element CE is an integral of the current value of the current I_wl during an arbitrary period. Thus, even if instantaneous external noise or the like occurs during this period, the noise or the like is averaged, and the influence thereof is relaxed.

One terminal of the switch circuit SW2 is coupled to the node ND4 and a first input terminal of the comparator 154. The other terminal of the switch circuit SW2 is coupled to an input terminal of the constant current circuit 153. Based on a control signal S2, the ON state and OFF state of the switch circuit SW2 are controlled. The control signal S2 is controlled, for example, by the sequencer 14.

The constant current circuit 153 flows a constant current Iconst. An output terminal of the constant current circuit 153 is grounded. For example, in a case where the switch circuit SW1 is in the OFF state and the switch circuit SW2 is in the ON state, the constant current circuit 153 discharges the capacitance element CE at a fixed rate (that is, lowers the voltage Vhold). The length of the period during which the constant current Iconst flows is based on the voltage value of the voltage Vhold. As the voltage Vhold is higher, the time of discharge becomes longer. Note that the magnitude of the constant current Iconst is arbitrary.

The comparator 154 is a voltage comparator. The first input terminal of the comparator 154 is coupled to the node ND4. That is, the voltage Vhold is applied to the first input terminal. A reference voltage VREF is applied to a second input terminal of the comparator 154. The voltage VREF is a positive voltage that is lower than a voltage VDD. An output terminal of the comparator 154 is coupled to the determination circuit 111 of the logic control circuit 11. In a case where the voltage Vhold is lower than the voltage VREF, the comparator 154 sends a signal FLG of “L” level to the determination circuit 111. On the other hand, in a case where the voltage Vhold is equal to or higher than the voltage VREF, the comparator 154 sends a signal FLG of “H” level to the determination circuit 111.

The determination circuit 111 counts the length of the period during which the signal FLG is at “H” level. If the count value is less than a preset determination value, the determination circuit 111 determines that a target word line WL is nondefective. On the other hand, if the count value is equal to or greater than the preset determination value, the determination circuit 111 determines that the target word line WL is defective. The determination circuit 111 transmits the determination result to the sequencer 14.

For example, in the detection circuit 151, if the constant current Iconst is decreased, the time of discharge of the voltage Vhold tends to become longer. That is, the period during which the signal FLG is at “H” level becomes longer. Thus, the count number in the determination circuit 111 increases, and the resolution of detection can be improved. In addition, by acquiring in advance the count number in a normal state as a reference, the determination circuit 111 can correct an element of variance or offset due to mismatching of circuity or background noise.

Based on the determination result, the sequencer 14 updates status information. For example, in a case where the target word line WL is determined to be defective, the sequencer 14 sets the block BLK including the target word line WL to be “bad block”. In the bad block, a new write operation is not executed. Based on the status information, the sequencer 14 controls the row decoder 18.

Based on the row address RA (block address BA), the row decoder 18 electrically couples the interconnect CG to a word line WL of one of the blocks BLK.

### 1.2. Threshold Voltage Distribution of Memory Cell Transistors

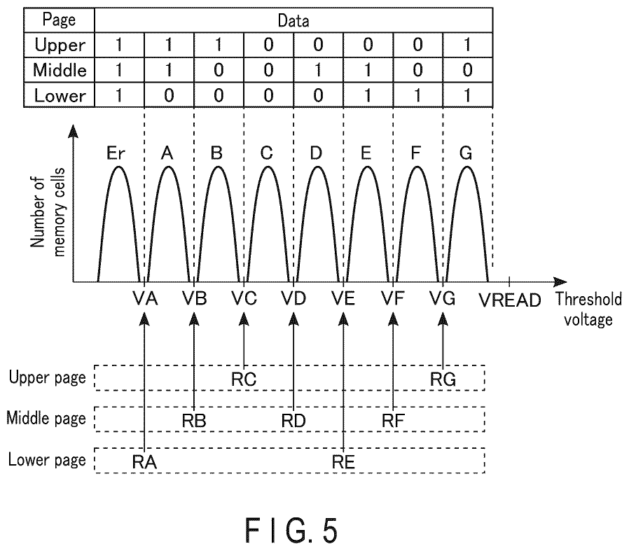

Next, referring to FIG. 5, an example of a threshold voltage distribution of memory cell transistors MC is described. FIG. 5 is a diagram illustrating a threshold voltage distribution and data assignment in a case where the memory cell transistor MC is a TLC that can store 3-bit data.

As illustrated in FIG. 5, in the case where the memory cell transistor MC stores 3-bit data, the distribution of threshold voltages thereof is divided into eight distributions. These eight threshold voltage distributions (threshold voltage ranges) are referred as an Er state, an A state, a B state, a C state, a D state, an E state, an F state, and a G state, in the order from the lowest threshold voltage.

Voltages VA to VG are verify voltages used for each of program verify operations of the A state to G state at the time of a write operation. The voltages VA to VG are voltages that are applied to a selected word line WL at the time of the program verify operation. A voltage VREAD is a voltage that is applied to non-selected word lines at the time of a read operation (at the time of the program verify operation). If the voltage VREAD is applied to the memory cell transistor MC, the memory cell transistor MC is set to the ON state, regardless of the stored data. The relationship between the voltages VA to VG and volage VREAD is VA<VB<VC<VD<VE<VF<VG<VREAD.

The Er state corresponds to an erase state of the memory cell transistor MC. Each of A state to G state corresponds to state in which charge is injected in the charge storage layer of the memory cell transistor MC and data is written. The threshold voltage of the memory cell transistor MC included in the Er state is less than the volage VA. The threshold voltages of the memory cell transistors MC included in the A state to the F state are the voltage VA or more and less than the voltage VB, . . . , and the voltage VF or more and less than the voltage VG, respectively. The threshold voltage of the memory cell transistor MC included in the G state is the voltage VG or more and less than the voltage VREAD.

The set value of the verify voltage and the set value of the read voltage, which correspond to each state, may be identical or different. Hereinafter, for the purpose of simple description, the case is described in which the set value of the verify voltage and the set value of the read voltage are identical.

Hereinafter, the read operations using the voltages VA to VG are referred as read operations RA to RG, respectively. The read operation RA determines whether the threshold voltage of the memory cell transistor MC is less than the voltage VA. The read operation RB determines whether the threshold voltage of the memory cell transistor MC is less than the voltage VB. The read operation RC determines whether the threshold voltage of the memory cell transistor MC is less than the voltage VC. The other read operations are similar.

As described above, the threshold voltage of each memory cell transistor MC belongs to any one of the eight threshold voltage distributions. Thereby, each memory cell transistor MC can take eight kinds of states. By assigning these states to data “000” to “111” of the binary notation, each memory cell transistor MC can store 3-bit data. Hereinafter, the 3-bit data is referred as “Lower bit”, “Middle bit” and “Upper bit” in the order from the lower bit. In addition, the set of Lower bits that the memory cell transistors MC included in the same cell unit CU is referred as “Lower page data”, the set of Middle bits is referred as “Middle page data”, and the set of Upper bits is referred as “Upper page data”.

In the example illustrated in FIG. 5, the data of “Upper bit/Middle bit/Lower bit” is assigned to the memory cell transistors MC included in each state, as follows.
Er state: “111” data
A state: “110” data
B state: “100” data
C state: “000” data
D state: “010” data
E state: “011” data
F state: “001” data
G state: “101” data.

In the case of reading data that is assigned in this manner, the Lower bit is determined by the read operations RA and RE. The Middle bit is determined by the read operations RB, RD, and RF. The Upper bit is determined by the read operations RC and RG. The values of the Lower bit, Middle bit and Upper bit are determined by two read operations, three read operations, and two read operations, respectively. Hereinafter, this data assignment is referred as “2-3-2 code”. Note that the data assignment to the Er to G states is not limited to the 2-3-2 code.

### 1.3. Word Line Determination Operation

Next, a word line determination operation is described. The word line determination operation is an operation of determining whether a target word line WL is nondefective or defective. The resistance value of a defective word line WL is higher than the resistance value of a nondefective word line WL. That is, the word line determination operation is an operation of determining whether the target word line WL has a low resistance.

For example, the word line determination operation may be executed as one of inspections in the manufacturing process of the semiconductor memory device 1, or may be executed by the user in order to confirm the state of the word line WL (an increase in resistance due to deterioration).

### 1.3.1. Voltage of Each of Interconnects in Word Line Determination Operation

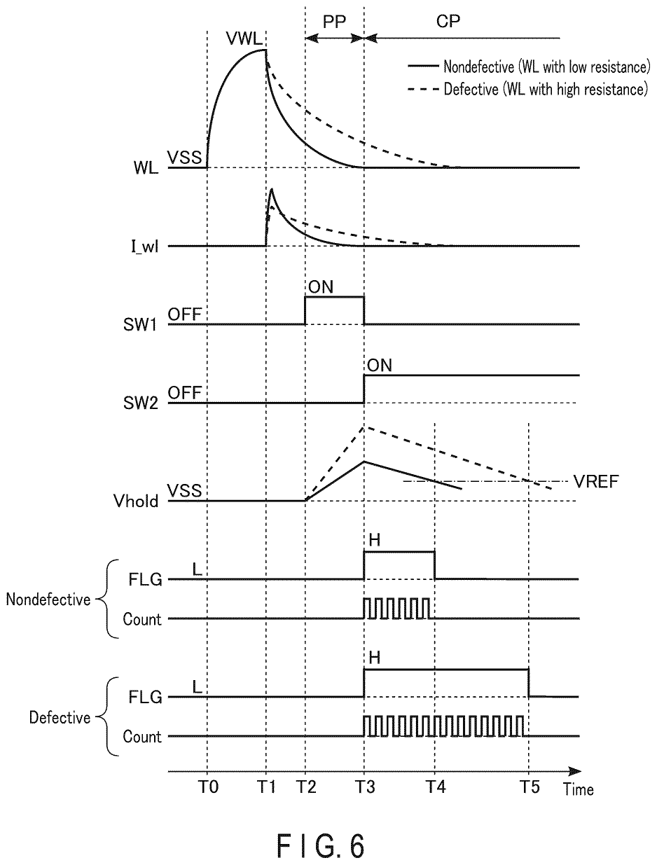

At first, referring to FIG. 6, an example of a voltage of each of interconnects in the word line determination operation is described. FIG. 6 is a timing chart illustrating an example of the voltage of each of the interconnects in the word line determination operation. In FIG. 6, a case in which the word line WL is nondefective (that is, low resistance) is indicated by a solid line, and a case in which the word line WL is defective (that is, high resistance) is indicated by a broken line.

As illustrated in FIG. 6, at first, during a period of time T0 to T1, a voltage VWL is applied to a word line WL of a determination target. More specifically, the voltage generator 15 applies the voltage VWL to the word line WL of the determination target via the interconnect CG and the row decoder 18. The voltage VWL is an arbitrary positive voltage. For example, the voltage VWL may be a voltage that is used in the read operation or in the program verify operation.

At time T1, the discharge of the word line WL is started. More specifically, the pre-driver 152 of the voltage generator 15 controls the transistor TN1. Thereby, the discharge current I_wl flows through the transistor TN1. In addition, by the current mirror, the current I_wl flows in the detection circuit 151. For example, as indicated by the solid line in FIG. 6, in the case of the nondefective word line WL (the word line WL with a low resistance), the voltage of the word line WL lowers relatively rapidly. On the other hand, as indicated by the broken line in FIG. 6, in the case of the defective word line WL (the word line WL with a high resistance), since the RC time constant of the defective word line WL is greater than the RC time constant of the nondefective word line WL, the voltage of the word line WL lowers relatively slowly. Compared to the nondefective word line WL, the defective word line WL has a lower maximum value of the current value of the discharge current I_wl immediately after the start of discharge, and decreases relatively slowly.

A period of time T2 to T3 is a precharge phase PP. In the precharge phase PP, the capacitance element CE is charged, and the charge amount thereof is converted into a voltage value of the voltage Vhold. During this period, in the detection circuit 151, the control signal S1 of the switch circuit SW1 is set at “H” level, and the control signal S2 of the switch circuit SW2 is set at “L” level. Thereby, the switch circuit SW1 is set to the ON state, and the switch circuit SW2 is set to the OFF state. As a result, the capacitance element CE is charged with the current I_wl. For example, the current amount of the current I_wl flowing during the period of time T2 to T3 is greater in the defective word line WL than in the nondefective word line WL. Thus, the charge amount charged in the capacitance element CE is greater in the defective word line WL than in the nondefective word line WL. That is, the voltage Vhold of the defective word line WL at time T3 is higher than the voltage Vhold of the nondefective word line WL at time T3.

A period after time T3 is a count phase CP. In the count phase CP, during the period in which the signal FLG is at “H” level, counting is executed. In the count phase CP, the voltage value of the voltage Vhold is converted into a count number. Since the count number corresponds to information of an integral value (total charge amount) of the discharge current, the magnitude of the discharge current I_wl can be determined from the count number.

At time T3, the control signal S1 of the switch circuit SW1 is set at “L” level, and the control signal S2 of the switch circuit SW2 is set at “H” level. Thereby, the switch circuit SW1 is set to the OFF state, and the switch circuit SW2 is set to the ON state. As a result, the discharge of electric charge that is stored in the capacitance element CE is started. The charge of the capacitance element CE is discharged via the switch circuit SW2 and the constant current circuit 153. That is, the voltage Vhold lowers. The voltage decrease rate (discharge rate) of the voltage Vhold is controlled to be constant by the constant current Iconst. Thus, as the voltage Vhold is higher, the discharge time becomes longer. The discharge time of the voltage Vhold is longer in the defective word line WL than in the nondefective word line WL.

The comparator 154 starts comparison between the voltage Vhold and the voltage VREF. The comparator 154 sets the signal FLG at “H” level during the period until the voltage Vhold lowers to less than the voltage VREF. The determination circuit 111 executes counting during the period in which the signal FLG is at “H” level.

For example, in the case of the nondefective word line WL, at time T4, the voltage Vhold lowers to less than the voltage VREF. During the period of time T3 to T4, the signal FLG is set at “H” level. The determination circuit 111 executes counting during the period of “H” level. For example, the count number is less than a determination value, and, based on this result, the determination circuit 111 determines that the word line WL is nondefective.

In addition, for example, in the case of the defective word line WL, at time T5, the voltage Vhold lowers to less than the voltage VREF. During the period of time T3 to T5, the signal FLG is set at “H” level. The determination circuit 111 executes counting during the period of “H” level. For example, the count number is equal to or greater than the determination value, and, based on the count number, the determination circuit 111 determines that the word line WL is defective.

### 1.3.2. Flow of Word Line Determination Operation

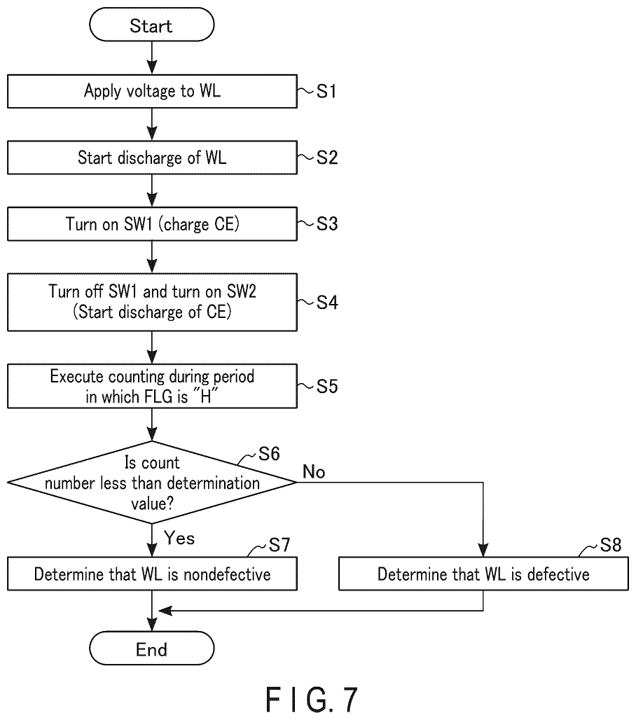

Next, referring to FIG. 7, an example of a flow of the word line determination operation is described. FIG. 7 is a flowchart illustrating an example of the flow of the word line determination operation.

As illustrated in FIG. 7, at first, the voltage VWL is applied to the word line of the determination target (S1).

Next, the discharge of the word line WL is started (S2). By the current mirror, the discharge current I_wl flows in the detection circuit 151.

Next, the switch circuit SW1 of the detection circuit 151 is set to the ON state (S3). Thereby, the capacitance element CE is charged. That is, the voltage Vhold rises.

Next, the switch circuit SW1 is set to the OFF state, and the switch circuit SW2 is set to the ON state (S4). Thereby, the charge stored in the capacitance element CE is discharged. Specifically, the voltage Vhold lowers.

The signal FLG is set at “H” level during the period until the voltage Vhold lowers to less than the voltage VREF. The determination circuit 111 executes counting during the period in which the signal FLG is at “H” level (S5).

If the count number is less than a preset determination value (S6_Yes), the word line WL is determined to be nondefective (S7).

On the other hand, if the count number is equal to or greater than the preset determination value (S6_No), the word line WL is determined to be defective (S8).

### 1.4. Advantageous Effects according to the Present Embodiment

With the configuration according to the present embodiment, a semiconductor memory device with improved reliability can be provided. Hereinafter, the advantageous effects are described in detail.

For example, one of causes of defects of the semiconductor memory device is an increase in resistance of the word line WL. In the manufacturing process of the semiconductor memory device, various inspections steps are executed in order to sort products. However, there is a case where a defect due to the increase in resistance of the word line WL cannot be extracted in the inspection step. In addition, there is a case where the word line WL deteriorates while the user uses the semiconductor memory device 1, and the resistance of the word line WL increases. There is a case where the defect due to the increase in resistance of the word line WL leads to a defect in read, and, in many cases, the defect in read cannot be remedied.

On the other hand, in the configuration according to the present embodiment, the semiconductor memory device 1 includes the detection circuit 151 and the determination circuit 111. The detection circuit 151 integrates the discharged current in an arbitrary period at the time of the discharge of the word line WL, and can detect a variation of the total charge amount of the discharge current. The determination circuit 111 converts the total charge amount into a count number, and determines whether the word line WL is nondefective or defective, based on the count number. Thereby, the semiconductor memory device 1 can execute the word line determination operation. That is, the semiconductor memory device 1 can detect a defect of the word line WL due to the increase in resistance. Thus, the reliability of the semiconductor memory device 1 can be improved.

Furthermore, with the configuration according to the present embodiment, the semiconductor memory device 1 can improve the detection accuracy of the resistance value of the word line WL, by controlling the voltage decrease rate of the voltage Vhold that is based on the total charge amount. Furthermore, the semiconductor memory device 1 can determine the degree of degradation of the word line WL, based on the resistance value of the word line WL.

Furthermore, with the configuration according to the present embodiment, the semiconductor memory device 1 can improve the detection accuracy of the resistance value of the word line WL, based on the count value. That is, the semiconductor memory device 1 can determine the degree of degradation of the word line WL.

### 2. Second Embodiment

Next, a second embodiment is described. In the second embodiment, two examples are illustrated in connection with a case where the program verify operation and the word line determination operation are combined. Hereinafter, different points from the first embodiment are mainly described.

### 2.1. Write Operation

At first, a write operation is described. The write operation includes a program operation and a program verify operation.

The program operation is an operation of raising the threshold voltage by injecting electrons in the charge storage layer of the memory cell transistor MC (or maintaining the threshold voltage by scarcely injecting electrons in the charge storage layer). Hereinafter, the word line WL that is coupled to the memory cell transistor MC of the write target is also referred to as “selected word line WL”. The other word lines WL are also referred to as “non-selected word lines WL”.

The program verify operation is an operation of reading data after the program operation, and determining whether the threshold voltage of the memory cell transistor MC has reached a target level (a state of a write target). Hereinafter, the case where the threshold voltage of the memory cell transistor MC has reached the target level is referred as “verify passed”, and the case where the threshold voltage of the memory cell transistor MC has not reached the target level is referred as “verify failed”. More specifically, for example, in the program verify operation, in a case where a fail bit number of read data is equal to or greater than a preset reference value, “verify failed” is determined.

By repeating the combination of the program operation and the program verify operation (hereinafter referred to as “program loop”), the threshold voltage of the memory cell transistor MC is raised up to the target level. At the time of repeating the program loop, the program voltage that is applied to the selected word line WL is stepped up in the program operation.

### 2.2. First Example of Combination of Program Verify Operation and Word Line Determination Operation

At first, a first example of the combination of the program verify operation and the word line determination operation is described. In the first example, a case is described in which, in the program verify operation, the word line determination operation is executed at the time of discharging the verify voltage VG applied to the selected word line WL.

### 2.2.1. Flow of Entirety of Write Operation

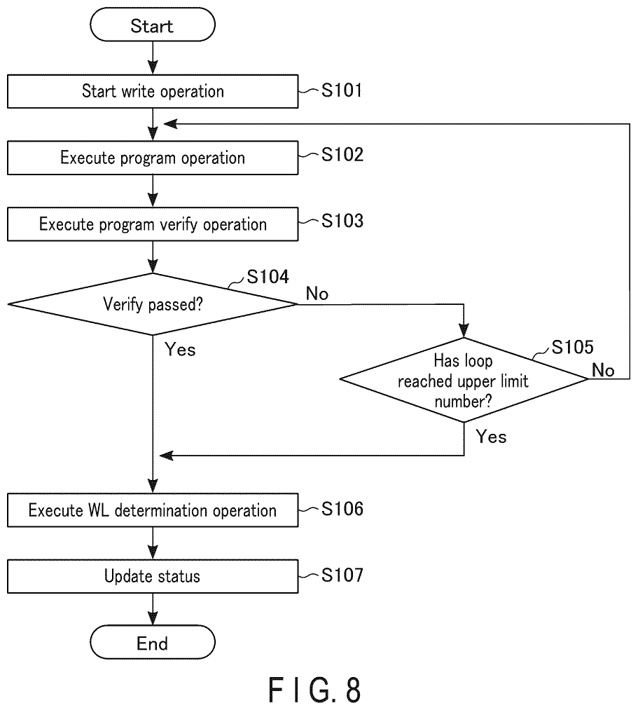

At first, referring to FIG. 8, a flow of the entirety of the write operation in the first example is described. FIG. 8 is a flowchart illustrating the flow of the write operation in the first example. In the example illustrated in FIG. 8, the case is described in which the word line determination operation for the selected word line is executed after the program verify operation is passed, but the timing of executing the word line determination operation is not limited to this. The count phase CP of the word line determination operation can be executed in parallel with the program operation and the program verify operation.

As illustrated in FIG. 8, based on a request from the memory controller, the sequencer 14 starts the write operation (S101).

At first, the sequencer 14 executes the program operation (S102).

Next, the sequencer 14 executes the program verify operation (S103).

If verify has been failed (S104_No), the sequencer 14 confirms whether a program loop number has reached a preset upper limit number.

If the program loop number has not reached the upper limit number (S105_No), the sequencer 14 steps up the set value of the program voltage that is applied to the selected word line WL. Then, the sequencer 14 advances to step S102 and repeats the program loop.

If verify has been passed (S104_Yes), or if the program loop number has reached the upper limit number (S105_Yes), the sequencer 14 executes the word line determination operation (S106). More specifically, in the last program verify operation, the verify voltage VG corresponding to the G state is applied to the selected word line WL. At the time of discharging the verify voltage VG, the word line determination operation is executed.

Based on the result of the word line determination operation, the sequencer 14 updates the status information (S107).

### 2.2.2. Voltage of each of Interconnects in Program Verify Operation and Word Line Determination Operation of First Example

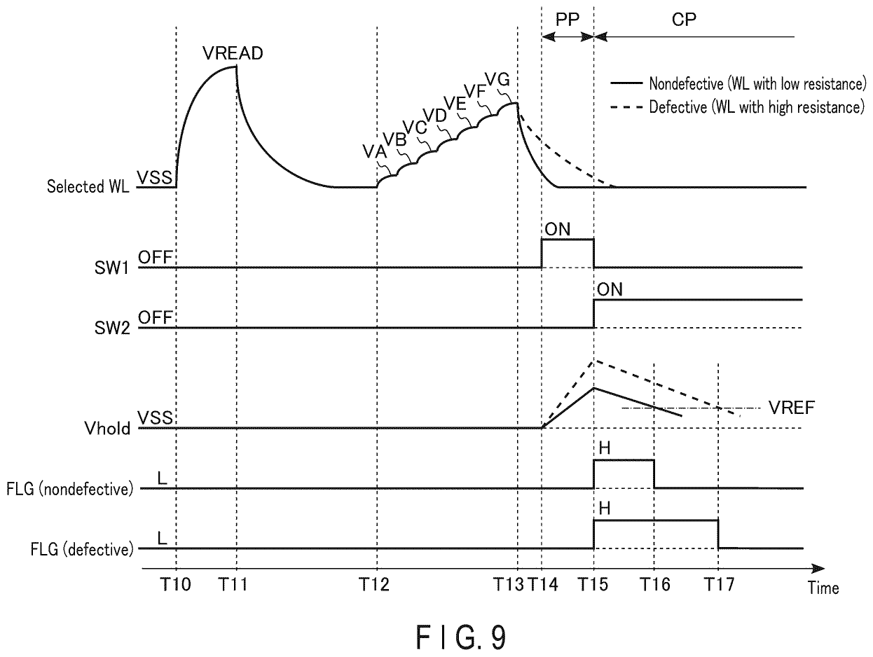

Next, referring to FIG. 9, a description is given of a voltage of each of interconnects in the program verify operation and the word line determination operation of the first example. FIG. 9 is a timing chart illustrating a voltage of each of interconnects in the program verify operation and the word line determination operation in the first example. In FIG. 9, a case in which the word line WL is nondefective (that is, low resistance) is indicated by a solid line, and a case in which the word line WL is defective (that is, high resistance) is indicated by a broken line.

As illustrated in FIG. 9, at first, during a period of time T10 to T11, the voltage READ is applied to the selected word line WL. For example, during the period of time T10 to T11, the select transistors ST1 and ST2 and memory cell transistors MC0 to MC7 of each NAND string are set to the ON state. For example, the charge of the channel of each NAND string NS is discharged.

Next, during a period of time T11 to T12, the voltage VREAD applied to the selected word line WL is discharged.

During a period of time T12 to T13, the verify voltage is applied to the selected word line WL. In the example illustrated in FIG. 9, the verify voltages VA to VG are successively applied. Note that in each program loop, the verify voltage that is applied to the selected word line WL is arbitrary. For example, in a case where the write is completed from the A state to the F state by repeating the program loop, only the verify voltage VG may be applied to the selected word line WL.

At time T13, the discharge of the verify voltage VG applied to the selected word line WL is started. As in the description using FIG. 6, in the case of the nondefective word line WL (the word line WL with a low resistance), the voltage of the selected word line WL lowers relatively rapidly. On the other hand, in the case of the defective word line WL (the word line WL with a high resistance), the voltage of the selected word line WL lowers relatively slowly.

A period of time T14 to T15 is a precharge phase PP. Like the period of time T2 to T3 illustrated in FIG. 6, in the detection circuit 151, the control signal S1 of the switch circuit SW1 is set at “H” level, and the control signal S2 of the switch circuit SW2 is set at “L” level. Thereby, the switch circuit SW1 is set to the ON state, and the switch circuit SW2 is set to the OFF state. As a result, the capacitance element CE is charged with the current I_wl.

A period after time T15 is a count phase CP. Independently from the write operation, the operation in the count phase CP can be executed on the background. Thus, for example, during the count phase CP, the write operation may be finished, or the next write operation or read operation may be executed.

At time T15, similarly with time T3 illustrated in FIG. 6, the control signal S1 of the switch circuit SW1 is set at “L” level, and the control signal S2 of the switch circuit SW2 is set at “H” level. The switch circuit SW1 is set to the OFF state, and the switch circuit SW2 is set to the ON state. Thereby, the discharge of the capacitance element CE is started. That is, the voltage Vhold lowers. The comparator 154 starts comparison between the voltage Vhold and the voltage VREF. The comparator 154 sets the signal FLG at “H” level during the period until the voltage Vhold lowers to less than the voltage VREF. The determination circuit 111 executes counting during the period in which the signal FLG is at “H” level.

For example, in the case of the nondefective word line WL, during the period of time T15 to T16, the signal FLG is set at “H” level. The determination circuit 111 executes counting during the period of “H” level. For example, the count number is less than a determination value, and, based on this result, the determination circuit 111 determines that the word line WL is nondefective.

In addition, for example, in the case of the defective word line WL, during the period of time T15 to T17, the signal FLG is set at “H” level. The determination circuit 111 executes counting during the period of “H” level. For example, the count number is equal to or greater than the determination value, and, based on the count number, the determination circuit 111 determines that the word line WL is defective.

### 2.3. Second Example of Combination of Program Verify Operation and Word Line Determination Operation

Next, a second example of the combination of the program verify operation and the word line determination operation is described. In the second example, a case is described in which, in the program verify operation, the word line determination operation is executed at the time of discharging the voltage VREAD applied to the selected word line WL. Hereinafter, different points from the first example are described.

### 2.3.1. Voltage of each of Interconnects in Program Verify Operation and Word Line Determination Operation of Second Example

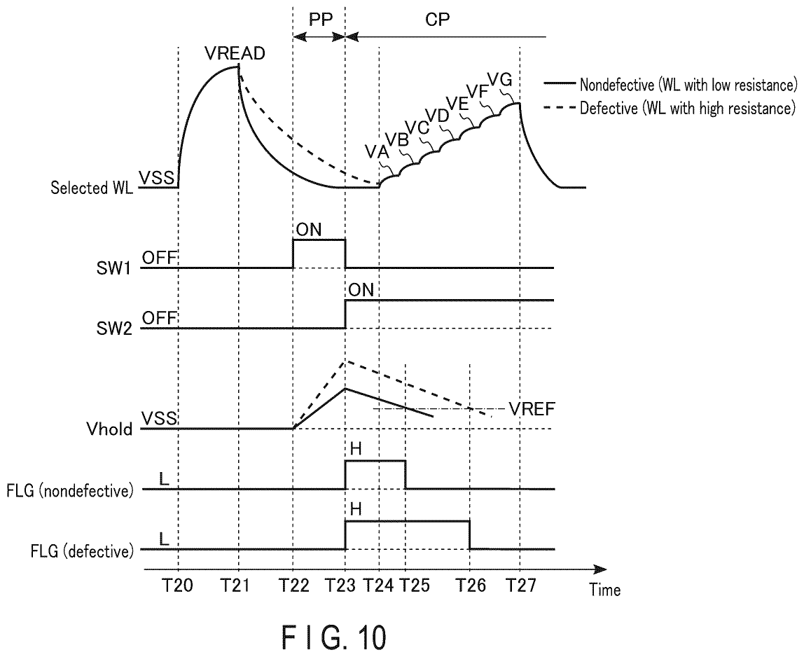

Next, referring to FIG. 10, a description is given of a voltage of each of interconnects in the program verify operation and word line determination operation of the second example. FIG. 10 is a timing chart illustrating a voltage of each of interconnects in the program verify operation and the word line determination operation of the second example. In FIG. 10, a case in which the word line WL is nondefective (that is, low resistance) is indicated by a solid line, and a case in which the word line WL is defective (that is, high resistance) is indicated by a broken line.

As illustrated in FIG. 10, at first, during a period of time T20 to T21, similarly with the period of time T10 to T11 of the first example, a voltage READ is applied to the word line WL.

During the period of time T21 to T24, the voltage VREAD of the selected word line WL is discharged. In the case of the nondefective word line WL (the word line WL with a low resistance), the voltage of the selected word line WL lowers relatively rapidly. On the other hand, in the case of the defective word line WL (the word line WL with a high resistance), the voltage of the selected word line WL lowers relatively slowly.

A period of time T22 to T23 is a precharge phase PP. Like the period of time T2 to T3 illustrated in FIG. 6, in the detection circuit 151, the control signal S1 of the switch circuit SW1 is set at “H” level, and the control signal S2 of the switch circuit SW2 is set at “L” level. Thereby, the switch circuit SW1 is set to the ON state, and the switch circuit SW2 is set to the OFF state. As a result, the capacitance element CE is charged with the current I_wl.

A period after time T23 is a count phase CP. The count operation is executed in parallel with the application of the verify voltage.

At time T23, similarly with time T3 illustrated in FIG. 6, the control signal S1 of the switch circuit SW1 is set at “L” level, and the control signal S2 of the switch circuit SW2 is set at “H” level. The switch circuit SW1 is set to the OFF state, and the switch circuit SW2 is set to the ON state. Thereby, the discharge of the capacitance element CE is started. That is, the voltage Vhold lowers. The comparator 154 starts comparison between the voltage Vhold and the voltage VREF. The comparator 154 sets the signal FLG at “H” level during the period until the voltage Vhold lowers to less than the voltage VREF. The determination circuit 111 executes counting during the period in which the signal FLG is at “H” level.

For example, in the case of the nondefective word line WL, during the period of time T23 to T25, the signal FLG is set at “H” level. The determination circuit 111 executes counting during the period of “H” level. For example, the count number is less than a determination value, and, based on this result, the determination circuit 111 determines that the word line WL is nondefective.

In addition, for example, in the case of the defective word line WL, during the period of time T23 to T26, the signal FLG is set at “H” level. The determination circuit 111 executes counting during the period of “H” level. For example, the count number is equal to or greater than the determination value, and, based on the count number, the determination circuit 111 determines that the word line WL is defective.

During a period of T24 to T27, similarly with time T12 to T13 illustrated in FIG. 9, the verify voltage is applied to the selected word line WL. Note that the period in which the verify voltage is applied to the selected word line WL may be longer than the count phase CP, or may be shorter than the count phase CP. That is, at least a part of the count phase CP can be executed at the same time as the application of the verify voltage.

At time T27, the discharge of the verify voltage VG applied to the selected word line WL is started.

### 2.4. Advantageous Effects According to the Present Embodiment

With the configuration according to the present embodiment, the same advantageous effects as in the first embodiment can be obtained.

Furthermore, with the configuration according to the present embodiment, the semiconductor memory device 1 can execute the word line determination operation in combination with the program verify operation. The semiconductor memory device 1 can execute the count phase CP of the word line determination operation on the background, independently from the write operation. Thereby, an increase in processing time of the write operation due to the word line determination operation can be suppressed. Therefore, the semiconductor memory device 1 can suppress a decrease in processing performance due to the word line determination operation.

Note that in the present embodiment, the case was described in which the program verify operation and the word line determination operation are combined, but the embodiment is not limited to this. The word line determination operation may be combined with the read operation, or may be combined with the program operation. In various kinds of operations, the word line determination operation can be executed in coincidence with the timing when the voltage applied to the selected word line WL is discharged. In this case, it is preferable that the voltage applied to the selected word line WL is higher.

### 3. Third Embodiment

Next, a third embodiment is described. In the third embodiment, a configuration of the detection circuit 151, which is different from the detection circuit 151 in the first embodiment, is described. Hereinafter, different points from the first embodiment are mainly described.

### 3.1. Configuration of Detection Circuit

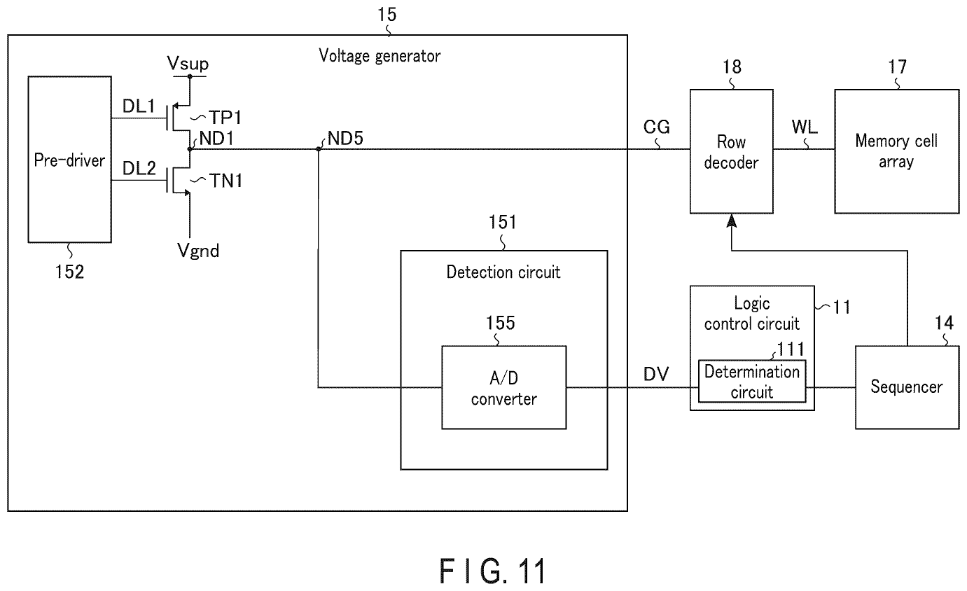

At first, referring to FIG. 11, an example of a configuration of the detection circuit 151 is described. FIG. 11 is a diagram schematically illustrating an example of couplings between the logic control circuit 11, the sequencer 14, the voltage generator 15, the memory cell array 17, and the row decoder 18. The example in FIG. 11 illustrates couplings corresponding to one word line WL, for the purpose of simple description.

As illustrated in FIG. 11, as in the description using FIG. 4, the voltage generator 15 further includes a pre-driver 152, a p-channel MOS transistor TP1, and an n-channel MOS transistor TN1.

The pre-driver 152 is coupled to the gate of the transistor TP1 via an interconnect DL1. For example, a power supply voltage Vsup is applied to the source of the transistor TP1. The drain of the transistor TP1 is coupled to a node ND1. The node ND1 is coupled to the row decoder 18 via the interconnect CG.

In addition, the pre-driver 152 is coupled to the gate of the transistor TN1 via an interconnect DL2. The drain of the transistor TN1 is coupled to the node ND1. A voltage Vgnd is applied to the source of the transistor TN1.

The detection circuit 151 includes an A/D converter 155. The A/D converter 155 converts an analog signal to a digital signal. An input terminal of the A/D converter 155 is coupled to the interconnect CG at a node ND5. An output terminal of the A/D converter 155 is coupled to the determination circuit 111. The A/D converter 155 (that is, detection circuit 151) sends to the determination circuit 111 a signal DV into which an analog voltage of the interconnect CG is digitally converted. The signal DV is a signal based on the discharge of the word line WL.

The determination circuit 111 of the present embodiment determines that the word line WL is nondefective, if the digital value of the signal DV is less than the preset determination value. On the other hand, the determination circuit 111 determines that the word line WL is defective, if the digital value of the signal DV is equal to or greater than the determination value. The determination circuit 111 sends the determination result to the sequencer 14. Note that the determination circuit 111 may determine the degree of degradation of the word line, based on the digital value of the signal DV.

### 3.2. Voltage of Word Line at Time of Word Line Determination Operation

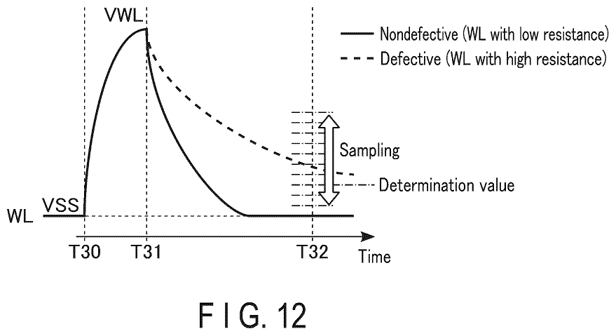

Next, referring to FIG. 12, a description is given of an example of the voltage of the word line WL in the word line determination operation. FIG. 12 is a timing chart illustrating an example of the voltage of the word line WL in the word line determination operation. In FIG. 12, a case in which the word line WL is nondefective (that is, low resistance) is indicated by a solid line, and a case in which the word line WL is defective (that is, high resistance) is indicated by a broken line.

As illustrated in FIG. 12, at first, at time T30, the voltage VWL is applied to the word line WL of the determination target. More specifically, the voltage generator 15 applies the voltage VWL to the word line WL of the determination target via the interconnect CG and the row decoder 18.

At time T31, the discharge of the word line WL is started. For example, in the case of the nondefective word line WL (the word line WL with a low resistance), the voltage of the word line WL lowers relatively rapidly. On the other hand, in the case of the defective word line WL (the word line WL with a high resistance), the voltage of the word line WL lowers relatively slowly.

At time T32 during the period of the discharge, the sampling of the voltage of the word line WL (interconnect CG) is executed. The A/D converter 155 digitally converts the voltage of the word line WL and generates the signal DV. The A/D converter 155 sends the signal DV to the determination circuit 111. In a case where the value of the signal DV is less than a determination value, the determination circuit 111 determines that the word line is nondefective. On the other hand, in a case where the value of the signal DV is equal to or greater than the determination value, the determination circuit 111 determines that the word line is defective.

### 3.3. Advantageous Effects according to the Present Embodiment

With the configuration according to the present embodiment, the semiconductor memory device 1 digitally converts the voltage value at an arbitrary timing at the time of discharge of the word line WL, and can determine, based on the digitally converted value, whether the word line WL is nondefective or defective. Thereby, the semiconductor memory device 1 can execute the word line determination operation. That is, the semiconductor memory device 1 can detect a defect of the word line WL due to the increase in resistance. Thus, the reliability of the semiconductor memory device 1 can be improved.

Furthermore, with the configuration according to the present embodiment, the semiconductor memory device 1 can improve the accuracy of detection of the resistance value of the word line WL in accordance with the number of bits of the A/D converter 155. Moreover, the semiconductor memory device 1 can determine the degree of degradation of the word line WL, based on the resistance value of the word line WL.

Note that the third embodiment can be combined with the second embodiment. Thereby, the same advantageous effects as in the second embodiment can be obtained.

### 4. Fourth Embodiment

Next, a fourth embodiment is described. In the fourth embodiment, a configuration of the detection circuit 151, which is different from the detection circuits 151 of the first and third embodiments, is described. Hereinafter, different points from the first and third embodiments are mainly described.

### 4.1. Configuration of Detection Circuit

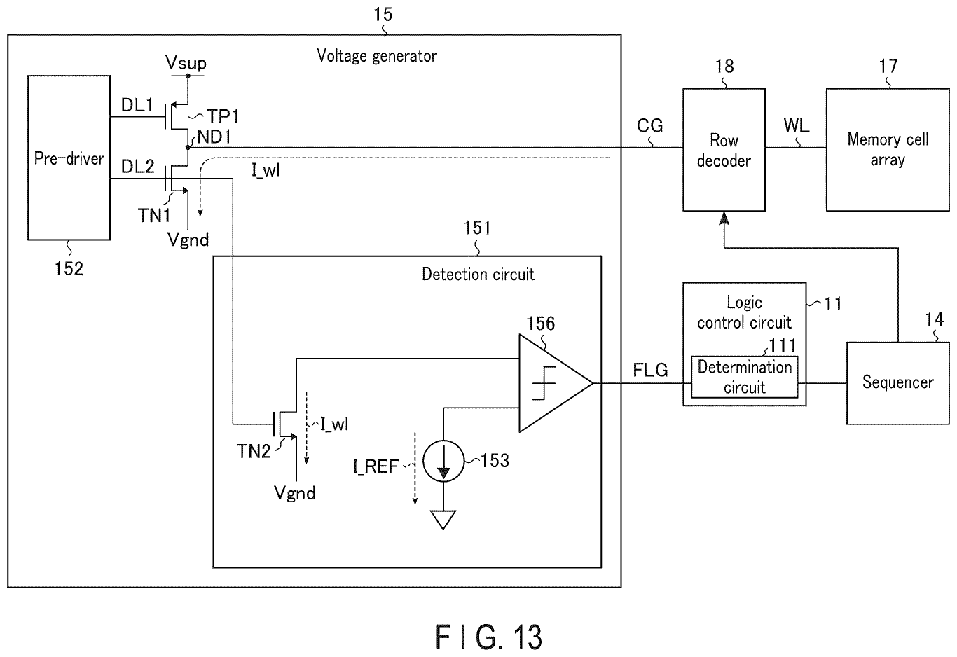

Referring to FIG. 13, an example of a configuration of the detection circuit 151 is described. FIG. 13 is a diagram schematically illustrating an example of couplings between the logic control circuit 11, the sequencer 14, the voltage generator 15, the memory cell array 17, and the row decoder 18. The example in FIG. 13 illustrates couplings corresponding to one word line WL, for the purpose of simple description.

As illustrated in FIG. 13, as in the description using FIG. 4, the voltage generator 15 further includes a pre-driver 152, a p-channel MOS transistor TP1, and an n-channel MOS transistor TN1.

The pre-driver 152 is coupled to the gate of the transistor TP1 via an interconnect DL1. For example, a power supply voltage Vsup is applied to the source of the transistor TP1. The drain of the transistor TP1 is coupled to a node ND1. The node ND1 is coupled to the row decoder 18 via the interconnect CG.

In addition, the pre-driver 152 is commonly coupled to the gate of the transistor TN1 and the detection circuit 151 via an interconnect DL2. The drain of the transistor TN1 is coupled to the node ND1. A voltage Vgnd is applied to the source of the transistor TN1.

For example, in a case of applying voltage to the word line WL (interconnect CG), the pre-driver 152 controls the gate voltage of the transistor TP1. For example, in a case of discharging the voltage that is applied to the word line WL (interconnect CG), the pre-driver 152 controls the gate voltage of the transistor TN1. At this time, a discharge current I_wl flows through the transistor TN1.

The detection circuit 151 includes an n-channel MOS transistor TN2, a constant current circuit 153, and a comparator 156.

The transistor TN2, together with the transistor TN1, constitutes a current mirror. The interconnect DL2 is coupled to the gate of the transistor TN2. The drain of the transistor TN2 is coupled to a first input terminal of the comparator 156. A voltage Vgnd is applied to the source of the transistor TN2. For example, if the discharge current I_wl flows through the transistor TN1, the same current I_wl flows through the transistor TN2.

The constant current circuit 153 flows a constant current I_REF. The constant current I_REF is an arbitrary reference current. An input terminal of the constant current circuit 153 is coupled to a second input terminal of the comparator 156. An output terminal of the constant current circuit 153 is grounded.

The comparator 156 is a current comparator. An output terminal of the comparator 156 is coupled to the determination circuit 111 of the logic control circuit 11. The comparator 156 compares the current I_wl and the current I_REF. In a case where the current I_wl is equal to or greater than the current I_REF, the comparator 156 sends a signal FLG of “H” level to the determination circuit 111. On the other hand, in a case where the current I_wl is less than the current I_REF, the comparator 156 sends a signal FLG of “L” level to the determination circuit 111.

If the signal FLG is at “L” level, the determination circuit 111 determines that a target word line WL is nondefective. On the other hand, if the signal FLG is at “H” level, the determination circuit 111 determines that the target word line WL is defective. The determination circuit 111 transmits the determination result to the sequencer 14.

### 4.2. Advantageous Effects according to the Present Embodiment

With the configuration according to the present embodiment, the semiconductor memory device 1 can determine whether the word line WL is nondefective or defective, by comparing the discharge current I_wl of the word line WL and the reference current I_REF. Thereby, the semiconductor memory device 1 can execute the word line determination operation. That is, the semiconductor memory device 1 can detect a defect of the word line WL due to the increase in resistance. Thus, the reliability of the semiconductor memory device 1 can be improved.

Note that the fourth embodiment can be combined with the second embodiment. Thereby, the same advantageous effects as in the second embodiment can be obtained.

### 5. Modifications and the Like

According to the above-described embodiments, a semiconductor memory device includes a memory cell array (17) including a memory cell (MC), a word line (WL) coupled to the memory cell, a row decoder (18) to which the word line is coupled, a first interconnect (CG) coupled to the row decoder, a voltage generator (15) configured to execute charge and discharge of the word line via the first interconnect and the row decoder, a detection circuit (151) included in the voltage generator and configured to output a first signal (FLG) based on the discharge of the word line, and a determination circuit (111) configured to determine whether the word line is nondefective or defective, based on the first signal.

With the configuration according to the above-described embodiment, the reliability of the semiconductor memory device 1 can be improved.

Aside from the above-described embodiments, various modifications are applicable.

Besides, the meaning of the term “coupling” in the above-described embodiments includes a state of indirect coupling, for example, with some element, such as a transistor or a resistor, being interposed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a memory cell;
a word line coupled to the memory cell;
a row decoder to which the word line is coupled;
a first interconnect coupled to the row decoder;
a voltage generator configured to execute charge and discharge of the word line via the first interconnect and the row decoder;
a detection circuit included in the voltage generator and configured to output a first signal based on the discharge of the word line; and
a determination circuit configured to determine whether the word line is nondefective or defective, based on the first signal.

2. The semiconductor memory device of claim 1, wherein the determination circuit is further configured to execute counting during a period in which the first signal is at a first logical level, to determine that the word line is nondefective in a case where a count number is less than a determination value, and to determine that the word line is defective in a case where the count number is equal to or greater than the determination value.

3. The semiconductor memory device of claim 2, wherein the period in which the first signal is at the first logical level is shorter in the case where the word line is nondefective than in the case where the word line is defective.

4. The semiconductor memory device of claim 2, wherein the count number is less in the case where the word line is nondefective than in the case where the word line is defective.

5. The semiconductor memory device of claim 2, wherein the detection circuit includes:
a capacitance element configured to be charged with electric charge based on a discharge current of the word line;
a current circuit used for discharge of the electric charge of the capacitance element; and
a comparator configured to output the first signal of the first logical level in a case where a first voltage of the capacitance element is equal to or higher than a reference voltage.

6. The semiconductor memory device of claim 5, wherein the first voltage of the capacitance element is lower in the case where the word line is determined to be nondefective than in the case where the word line is determined to be defective.

7. The semiconductor memory device of claim 1, wherein a resistance value of the word line that is determined to be nondefective is lower than a resistance value of the word line that is determined to be defective.

8. The semiconductor memory device of claim 1, wherein the memory cell includes a charge storage layer.

9. The semiconductor memory device of claim 1, wherein
a write operation repeatedly executes a program loop including a program operation and a program verify operation, and
determination in the determination circuit is executed at a time when a verify voltage applied to the word line is discharged in the program verify operation.

10. The semiconductor memory device of claim 9, wherein the determination in the determination circuit is executed after the program verify operation has been passed.

11. The semiconductor memory device of claim 1, wherein
a write operation includes a program operation and a program verify operation, and
determination in the determination circuit is executed at a time when a second voltage, which is applied before a verify voltage is applied to the word line and is higher than the verify voltage, is discharged in the program verify operation.

12. The semiconductor memory device of claim 11, wherein at least a part of the determination in the determination circuit is executed at the same time as the application of the verify voltage.

13. The semiconductor memory device of claim 1, wherein the detection circuit includes an A/D converter configured to output the first signal into which a discharge volage of the word line is digitally converted.

14. The semiconductor memory device of claim 11, wherein the determination circuit is configured to determine that the word line is nondefective in a case where a digital value of the first signal is less than a determination value, and to determine that the word line is defective in a case where the digital value is equal to or greater than the determination value.

15. The semiconductor memory device of claim 1, wherein the detection circuit includes a current comparator configured to compare a discharge current of the word line and a reference current.

16. The semiconductor memory device of claim 15, wherein the determination circuit is configured to determine that the word line is nondefective in a case where the discharge current is lower than the reference current, and to determine that the word line is defective in a case where the discharge current is equal to or greater than the reference current.
